(19) United States
(12) Patent Application Publication
(10) Pub. No.: US 2019/0362951 A1
(43) Pub. Date: Nov. 28, 2019

(54) PVD REACTOR WITH MAGNETIC ROTATION MECHANISM

(71) Applicants: Cheng-Feng Li, Taipei City (TW); Mu Chun Ho, Taipei City (TW)

(72) Inventors: Cheng-Feng Li, Taipei City (TW); Mu Chun Ho, Taipei City (TW)

(21) Appl. No.: 15/989,196

(22) Filed: May 25, 2018

(51) Int. Cl. H01J 37/34; F16H 1/06; H01J 37/32

(52) U.S. Cl. CPC H01J 37/3455; F16H 1/06; H01J 2237/3323; H01J 37/347; H01J 37/32669

(57) ABSTRACT

A PVD reactor with a magnetic rotation mechanism comprises a base installed to a top of an interior of a reactor; a retaining gear fixedly installed at a bottom surface of the base; a central shaft rotatably passing through the base and the retaining gear; a driver for driving the central shaft to rotate; a rotation arm having a receiving groove for receiving the retaining gear; a rotation gear rotatably installed within the receiving groove and engaged with the retaining gear; a center of the rotation gear having a gear shaft; a magnetic disk installed to a lower end of the gear shaft; the magnetic disk containing a plurality of disk bodies which are parallel and a plurality of magnets; the magnets being formed as two spinal shapes which are alternatively arranged and contains two opposite polarities; and a balance block serving to balance the weight of the magnetic disk.

### FIELD OF THE INVENTION

The present invention is related to PVD (physical vapor deposition) reactors, and in particular to a PVD reactor with a magnetic rotation mechanism.

### BACKGROUND OF THE INVENTION

PVD (physical vapor deposition) is a sputter process and is widely used in the processes of semiconductor manufacturing circuits, especially, in the deposition layers of wafers or other substrates.

Referring to FIG. 1, a PVD reactor is illustrated for sputter process. In that, a reactor 10 is installed with a target 11. A lower side of the target 11 is installed with a tray 12 for supporting a wafer 13 (or a substrate), and a magnetic disk 14 is installed at an upper side of the target 11. A plurality of magnets 140 (permanent magnets) are installed on the magnetic disk 14 and polarities of the magnets 140 are vertically arranged. The magnets 140 are arranged as many circles which are enclosed one by one. The polarities of adjacent circles are opposite. The magnetic disk 14 is combined to a lower end of the central shaft 15. Another end of the central shaft 15 is combined to a driver 16. The driver 16 drives the magnetic disk 14 to rotate. Therefore, non active working air (such as argon) can be inputted to a vacuum reactor 10 at a lower side of the target 11. The magnetic field generated by the magnetic disk 14 causes electrons to rotate in a specific area to collide argon atoms so as to generate chain reactions of argon ions and electrons, that is, to generate plasma. Therefore, positive argon ions are attached to the target 11 which is biased to be electrically negative and thus atoms are sputtered from the target 11. Some of the sputtering atoms are deposited on the wafer 13. The density of the plasma is controlled by the magnetic field generated by the magnets 140. The magnetic field could trap the electrons so as to increase the density of the plasma to increase the efficiency of sputter.

However, the prior art magnetic disk 14 of PVD reactor 10 is combined to the central shaft 15 by the center thereof. Rotation of the magnetic disk 14 is around the central shaft 15. Magnetic field generated by the magnetic disk 14 also rotates around the central shaft 15. It is very easy to form with closed tracks as illustrated in FIG. 2. Therefore, in sputtering process, the closed track will induce that a deep etching trench “a” is formed in a specific area of the target 11. This deep etching trench “a” will determine the lifetime of the target 11. If the etching speed in the deep etching trench “a” is quicker than the average etching speed of the target, it will induce that some areas of the target 11 are especially thin and thus the target 11 cannot be further used. A frequent condition is that the target 11 needs to be updated because the thickness of the thinnest area of the target 11 is not matched to the specification about the thickness of the target 11, but other area of the target 11 is still usable. Even in some conditions, that only 20% weight percentage of the target 11 is used, but the target 11 is needed to be updated. It will induce the use of the target 11 to be very low. As a result, the cost in manufacturing is high. If the wafer 13 has a deep hole a1 with ratio of deep to width being greater than 1, at a position of the wafer 13 near a right side of the target 11, a left wall of the deep hole a1 (or deep trench) become lack of plating atom. Thus the thickness of the plating film a2 is thinner as illustrated in FIG. 3. Another, at a position of the wafer 13 near a left side of the target 11, a right wall of the deep hole a1 (or deep trench) become lack of plating atom. Thus the thickness of the plating film a2 is thinner as illustrated in FIG. 4. Therefore, the uniformity of the hole is not good. Since the prior art magnetic disk 14 will induce a bad uniformity, proceeding CMP flatten needs more grinding time to get a better uniformity as the dashed lines shown in FIG. 5. As a result the proceeding working time is increased and thus the working efficiency is affected.

### SUMMARY OF THE INVENTION

Accordingly, the object of the present invention is to provide PVD reactor with a magnetic rotation mechanism, in that the present invention provides a reactor for PVD, in the present invention, the magnetic disk rotates with the central shaft and at the same time it rotates around its center so that the whole target is scanned with a fixed period by the magnetic field generated by the magnetic disk. Therefore, the use of the target in the whole sputtering process is promoted greatly and the uniformity of the film generated in the sputtering process is improved greatly.

To achieve above object, the present invention provides a PVD reactor with a magnetic rotation mechanism, comprising: a base fixedly installed to a top of an interior of a reactor; a retaining gear fixedly installed at a bottom surface of the base by using a plurality of retaining studs; a central shaft rotatably passing through the base and the retaining gear; an upper end of the central shaft being connected to a driver so that the driver could drive the central shaft to rotate, and a lower end of the central shaft protruding to a lower side of the retaining gear; a rotation arm retained to a lower end of the central shaft; one end of the rotation arm having a receiving groove for receiving the retaining gear; a rotation gear rotatably installed within the receiving groove and engaged with the retaining gear; a center of the rotation gear having a gear shaft which downwards penetrates through rotation arm; a magnetic disk installed to a lower end of the gear shaft; the magnetic disk containing a plurality of disk bodies which are parallel and a plurality of magnets; the magnets being formed as two spinal shapes which are alternatively arranged and contains two opposite polarities; and a balance block firmly secured to another end of the rotation arm and the retaining gear is between the balance block and the magnetic disk; the balance block serving to balance the weight of the magnetic disk.

### BRIEF DESCRIPTION OF THE DRAWINGS

FIG. 1 is a structural schematic view of a prior art PVD reactor.

FIG. 2 is a drawing simulating the magnetic field of the prior art PVD reactor and a partial enlarged view thereof is shown.

FIG. 3 is an enlarged cross sectional view of part A in FIG. 1.

FIG. 4 is an enlarged cross sectional view of part B in FIG. 1.

FIG. 5 shows the thickness after CMP flatten process of a wafer in the PVD reactor.

FIG. 6 is an exploded schematic view of the present invention.

FIG. 7 is an enlarged schematic view about the present invention.

FIG. 8 is an assembled enlarged cross sectional view of the present invention.

FIG. 9 is a plan enlarged schematic view about the magnetic disk of the present invention.

FIG. 10 is a partial enlarged view about the simulation of magnetic field of the present invention.

FIG. 11 is a schematic view showing the consumption of the target according to the present invention.

FIG. 12 is a partial enlarged cross sectional view showing a right side of a plated wafer according to the present invention.

FIG. 13 is a partial enlarged cross sectional view showing a left side of a plated wafer according to the present invention.

FIG. 14 is a schematic view showing the thickness after grinding in the CMP flatten process to a wafer according to the present invention.

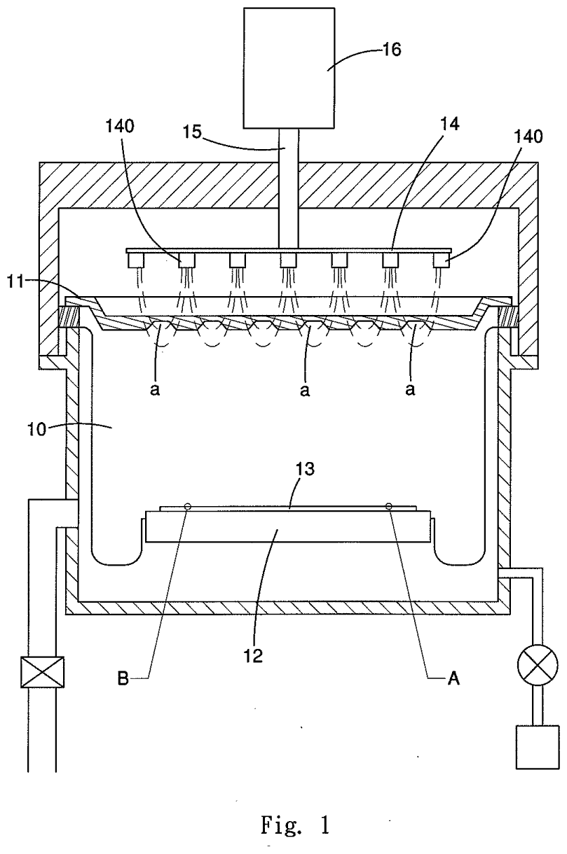

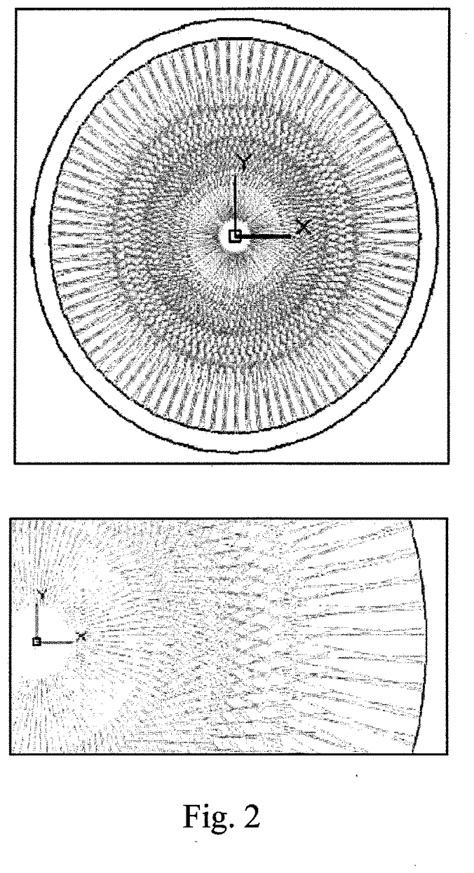

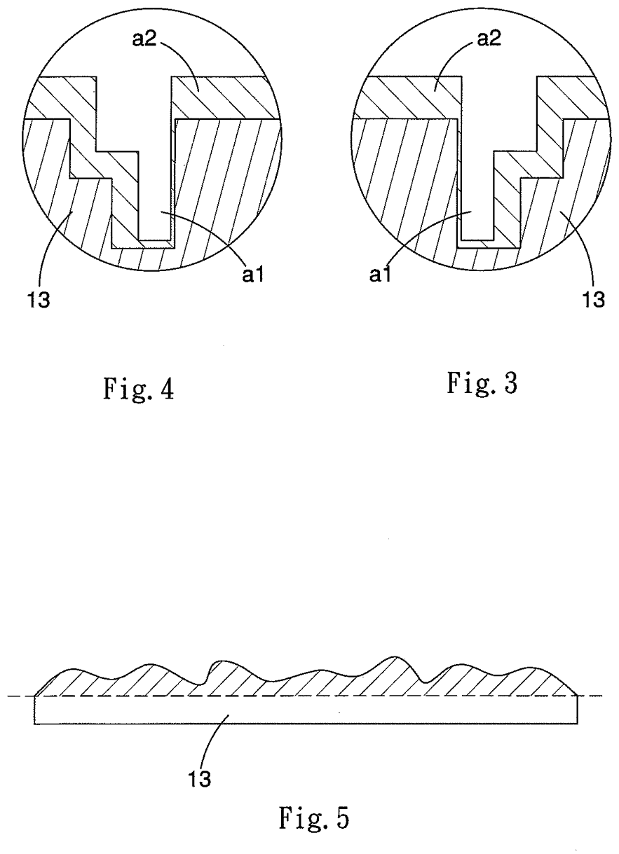

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

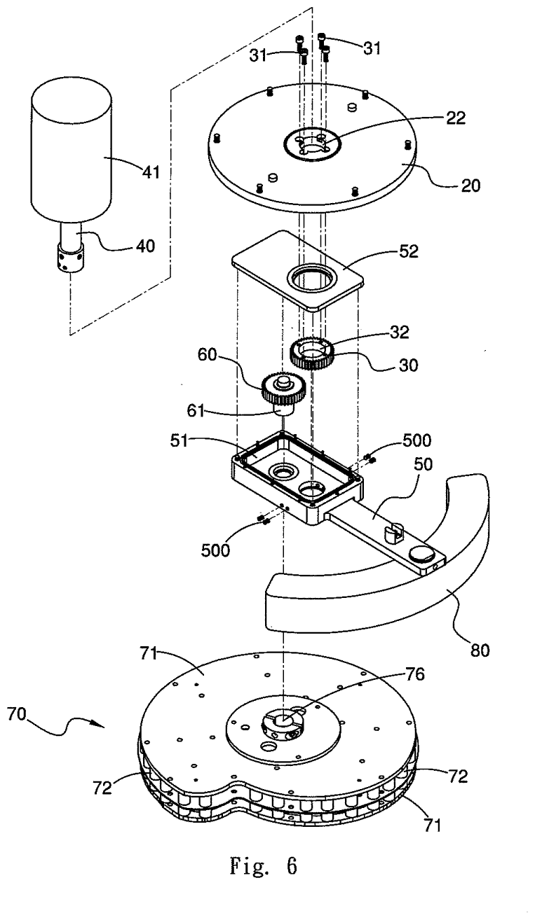

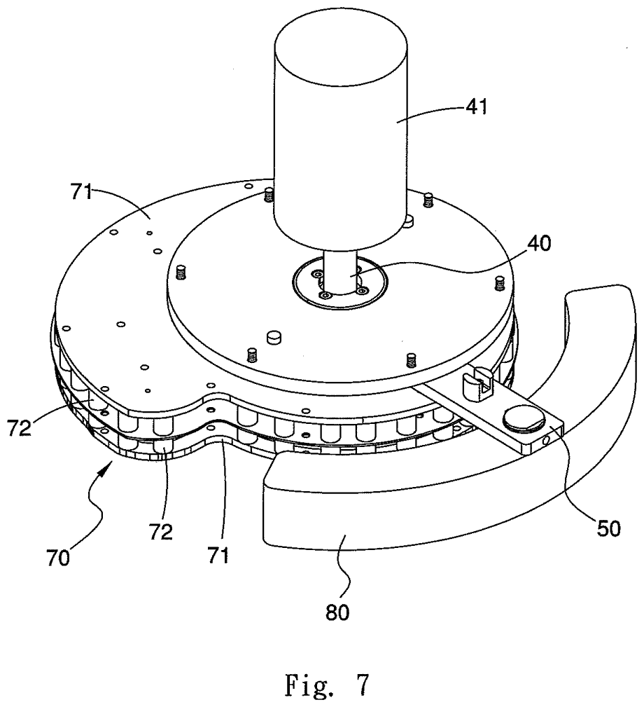

Referring to FIGS. 6 to 8, the structure of the present invention is illustrated. The present invention includes the following elements.

A base 20 is fixedly installed to a top of an interior of a reactor 21. The base 20 has a through hole 22.

A retaining gear 30 is fixedly installed at a bottom surface of the base 20 by using a plurality of retaining studs 31. A center of the retaining gear 30 has a penetrating axial hole 32.

A central shaft 40 rotatably passes through the through hole 22 of the base 20 and the axial hole 32 of the retaining gear 30. An upper end of the central shaft 40 is connected to a driver 41 so that the driver 41 could drive the central shaft 40 to rotate, and a lower end of the central shaft 40 protrudes to a lower side of the retaining gear 30.

A rotation arm 50 has an oblong structure and is retained to a lower end of the central shaft 40 by using a plurality of combining studs 500. One end of the rotation arm 50 has a receiving groove 51 for receiving the retaining gear 30. A sealing cover 52 covers on an upper opening of the receiving groove 51 for water proof.

A rotation gear 60 is rotatably installed within the receiving groove 51 and is engaged with the retaining gear 30. A center of the rotation gear 60 has a gear shaft 61 which downwards penetrates through rotation arm 50.

The magnetic disk 70 is installed to a lower end of the gear shaft 61. The magnetic disk 70 contains a plurality of disk bodies 71 which are parallel and a plurality of magnets 72. Each magnet 72 has a round cylinder shape and is a permanent magnet. The magnets 72 are formed as two spinal shapes which are alternatively arranged and contains two opposite polarities. The disk body 71 rotates synchronously with the rotation of the rotation gear 60.

A balance block 80 is firmly secured to another end of the rotation arm 50 and the retaining gear 30 is between the balance block 80 and the magnetic disk 70. The balance block 80 serves to balance the weight of the magnetic disk 70.

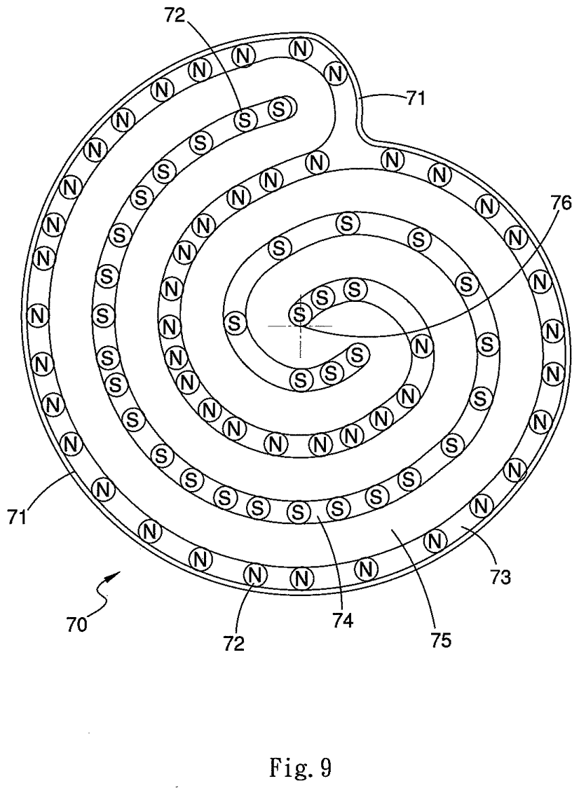

Referring to FIG. 9, it is illustrated that the magnets 72 are formed as an outer pole 73 and an internal pole 74. Each of the outer pole 73 and internal pole 74 has a spiral shape. The internal pole 74 is formed by one specific polarity, and most of the outer pole 73 is formed by another polarity opposite to the polarity of the internal pole 74, while an inner most end of the outer pole 73 is formed with polarity same as that of the internal pole 74.

A permanent gap 75 is formed between the outer pole 73 and the internal pole 74 for dividing the outer pole 73 and the internal pole 74 and defines a high density plasma area. The permanent gap 75 has a shape of a spiral area so that closed current coil is built in the plasma. This is a way to effectively retain the plasma.

In the present invention, the rotation center 76 of the magnetic disk 70 is an inner end of the internal pole 74. A size f the magnetic disk 70 is almost equal to an effectively area of the target 90. The magnetic disk 70 is as a five trail magnetic electric tube because any path is initiated from the rotation center 76 and runs across the five trail magnetic electric tube with an arc over 180 degrees.

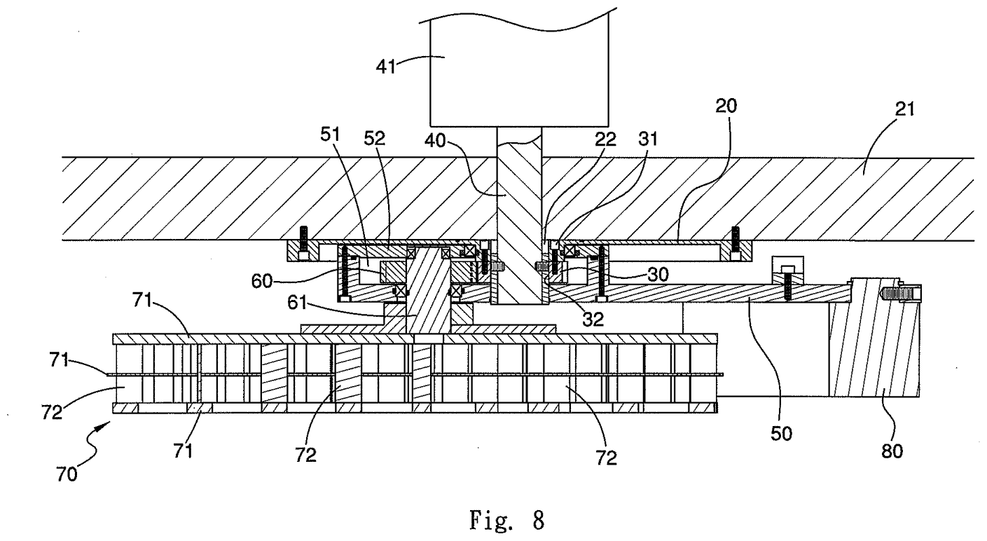

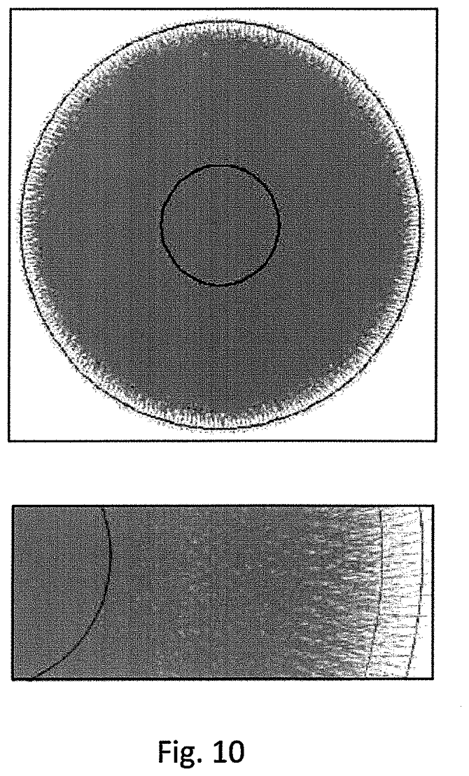

Referring to FIG. 8, it is shown that when the driver 41 drive the rotation center 76 to rotate, the central shaft 40 will drive the rotation arm 50 to rotate. Then the rotation gear 60 in the rotation arm 50 will rotate around the retaining gear 30. Because the rotation gear 60 is engaged to the retaining gear 30, when the rotation gear 60 rotates around the retaining gear 30, the rotation gear 60 will rotate around a center itself. The magnetic disk 70 is combined to the rotation gear 60 at the same axis, and thus the magnetic disk 70 will rotate with the rotation gear 60 (that is, when it rotates around the central shaft 40, it will rotate by itself). The magnetic line due to the rotation of the magnetic disk 70 encloses 90% of the target, as illustrated in FIG. 10.

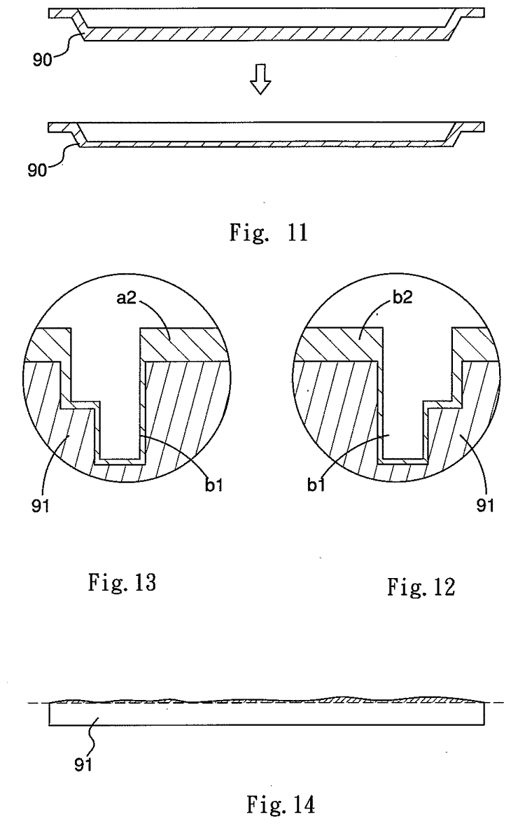

Therefore, in sputtering, all part of the target 90 is scanned within a fixed period. Thus, all the material of the target 90 will be bombed out by argon uniformly. The target 90 becomes thinner with the time, as illustrated in FIG. 11. The use of the target 90 is increased greatly.

Because the magnetic field rotates uniformly, the two lateral walls of the hole b 1 can have a film with a uniform thickness, as illustrated in FIGS. 12 and 13. Besides, since the thickness of the film of the wafer 91 is more uniform, the proceeding CMP flatten process is unnecessary to grind too much material (see the inclines lines shown in FIG. 14). Therefore, the proceeding finishing work is more easily with less time and labors.

The present invention provides a reactor for PVD, in the present invention, the magnetic disk 70 rotates with the central shaft 40 and at the same time it rotates around its center so that the whole target 90 is scanned with a fixed period by the magnetic field generated by the magnetic disk 70.

Therefore, the use of the target 90 in the whole sputtering process is promoted greatly and the uniformity of the film generated in the sputtering process is improved greatly.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A PVD reactor with a magnetic rotation mechanism, comprising:
a base fixedly installed to a top of an interior of a reactor;
a retaining gear fixedly installed at a bottom surface of the base;
a central shaft rotatably passing through the base and the retaining gear;
an upper end of the central shaft being connected to a driver so that the driver could drive the central shaft to rotate, and a lower end of the central shaft protruding to a lower side of the retaining gear;
a rotation arm retained to a lower end of the central shaft; and one end of the rotation arm having a receiving groove for receiving the retaining gear;
a rotation gear rotatably installed within the receiving groove and engaged with the retaining gear; a center of the rotation gear having a gear shaft which downwards penetrates through rotation arm;
a magnetic disk installed to a lower end of the gear shaft; the magnetic disk containing a plurality of disk bodies which are parallel and a plurality of magnets; the magnets being formed as two spinal shapes which are alternatively arranged and contains two opposite polarities; and
a balance block firmly secured to another end of the rotation arm and the retaining gear is between the balance block and the magnetic disk; the balance block serving to balance the weight of the magnetic disk.

2. The PVD reactor with a magnetic rotation mechanism as claimed in claim 1, wherein the base has a through hole; and a center of the retaining gear having a penetrating axial hole; the central shaft rotatably passes through the through hole of the base and the axial hole of the retaining gear.

3. The PVD reactor with a magnetic rotation mechanism as claimed in claim 1, wherein each magnet is a permanent magnet.

4. The PVD reactor with a magnetic rotation mechanism as claimed in claim 1, wherein the rotation arm has an oblong structure and is retained to a lower end of the central shaft; and a sealing cover covers on an upper opening of the receiving groove for water proof.

5. The PVD reactor with a magnetic rotation mechanism as claimed in claim 1, wherein the retaining gear is retained to a bottom of the base by using a plurality of studs.

6. The PVD reactor with a magnetic rotation mechanism as claimed in claim 1, wherein the rotation arm is fixed to a lower end of the central shaft by using a plurality of studs.

7. The PVD reactor with a magnetic rotation mechanism as claimed in claim 1, wherein the magnets are formed as an outer pole and an internal pole; each of the outer pole and internal pole has a spiral shape; the internal pole is formed by one specific polarity, and most of the outer pole is formed by another polarity opposite to the polarity of the internal pole, while an inner most end of the outer pole is formed with polarity same as that of the internal pole.

8. The PVD reactor with a magnetic rotation mechanism as claimed in claim 7, wherein a permanent gap is formed between the outer pole and the internal pole for dividing the outer pole and the internal pole and defines a high density plasma area; and the permanent gap has a shape of a spiral area.

9. The PVD reactor with a magnetic rotation mechanism as claimed in claim 1, wherein a rotation center of the magnetic disk is an inner end of the internal pole; a size f the magnetic disk is almost equal to an effectively area of the target.
